(19) United States
(12) Patent Application Publication
(10) Pub. No.: US 2004/0123800 A1
(43) Pub. Date: Jul. 1, 2004

(54) Showerheads

(76) Inventor: Ole Schlottmann, Cardiff (GB)

Correspondence Address: VOLENTINE FRANCOS, P.L.L.C., Suite 150, 12200 Sunrise Valley Drive, Reston, VA, 20191, US

(21) Appl. No.: 10/625,671

(22) Filed: Jul. 24, 2003

Related U.S. Application Data
(60) Provisional application No. 60/401,769, filed on Aug. 8, 2002.

(30) Foreign Application Priority Data
Aug. 8, 2002 (GB) 0218371.3

(51) Int. Cl. C23C 16/00

(52) U.S. Cl. 118/715; 118/723 E

(57) ABSTRACT

A showerhead for substrate processing including a gas inlet leading to a gas reservoir. A faceplate including a plurality of orifices is fitted between the reservoir and a processing space. The showerhead further includes a sheet including a plurality of orifices, the sheet orifices being smaller in size than the minimum diameter of the faceplate orifices. The sheet is fitted in or on the showerhead such that the fluid passes to the process space from the reservoir via the sheet orifices.

### FIELD OF THE INVENTION

The present invention relates to showerheads for substrate processing.

### BACKGROUND TO THE INVENTION

Showerheads have become a commonplace gas inlet for chemical vapour processing of substrates and in particular for the vacuum processing of wafers and flat panels for the production of, e.g. microelectronics, flat panel displays and microelectromechanical systems (MEMS).

Showerhead gas inlets are popular because they enable the integration of an electrode or counter electrode that is typically temperature controlled and of uniform temperature across its face and provides a relatively uniform gas distribution over an area sufficient to provide uniform processing of the opposing workpiece. More recently, assemblies have been produced where the showerhead assembly itself forms one wall of the vacuum process chamber. It has also become possible to increase semiconductor wafer size to 300 mm and in this case the showerhead itself must be of at least that diameter to ensure uniform vapour processing.

The face of the showerhead therefore needs to be mechanically strong, made of electrically conductive material, thermally conductive and pierced with holes to allow gas to pass through the face of the showerhead from a reservoir to the process chamber. To enable the showerhead to function there must be a pressure differential between the reservoir and the process chamber and this leads to a requirement for small holes. The face of the showerhead is frequently made of aluminium, a material particularly suited to semiconductor wafer processing. U.S. Pat. No. 6,379,466 shows an example of a showerhead design as described above. A further example can be seen in U.S. Pat. No. 6,024,779 where a centrally located plurality of through-bores to the upstream face of a manifold define a gas flow path from an upstream gas source to a wafer in a chemical vapour deposition reactor.

The practical result of these requirements is that thousands of tiny holes must be drilled through a thickness of a metal such as aluminium. These holes must all be drilled reliably and accurately and even when this is achieved, the holes are not smooth walled but rough and contain tiny burrs. This presents numerous problems. In particular cutting fluids and even cleaning materials may be trapped by this surface roughness and chemical methods of smoothing or cleaning run the risk, if they are effective, of increasing the hole size. Also, polishing or other mechanical processes (e.g. cleaning the showerhead face) may also affect the hole size and/or smear material into the holes, and this can partially block them.

In an existing attempt to overcome at least some of these problems, the holes formed are not of even diameter through the entire depth of the showerhead. The holes are considerably bigger through most of the depth and are only made at the required gas flow-controlling bore size through a small part of the showerhead face. In one example in U.S. Pat. No. 4,854,263, a faceplate of 0.4 inches (about 10.16 mm) thickness is drilled with 1,500 holes in a 6 inch (about 152.4 mm) diameter faceplate where the through hole is of 0.016 inches (about 0.406 mm) diameter and 0.05 inches (about 1.27 mm) depth. The remaining thickness of the faceplate is drilled with holes of a much larger diameter. In another example in U.S. Pat. No. 6,024,799 the upstream side of the gas faceplate of 0.4 inches (about 10.16 mm) thickness is drilled with holes of 0.110 inches (about 2.8 mm) and the downstream side with holes of 0.213 inches (about 5.4 mm). These holes are then connected by through holes of about 0.016 inches (about 0.4 mm) in diameter and 0.08 inches (about 2.0 mm) in length. This counterbore approach still however does not directly address many of the fundamental problems with showerhead hole formation being that they must be precision drilled through a thickness of the gas distribution faceplate.

### SUMMARY OF THE INVENTION

According to a first aspect of the present invention there is provided a showerhead for substrate processing including:

a gas inlet leading to a gas reservoir;

a faceplate fitted between the reservoir and a processing space, the faceplate including a plurality of orifices, and

a sheet including a plurality of orifices, the sheet orifices being smaller in size than the minimum diameter of the faceplate orifices,

wherein the sheet is fitted in or on the showerhead such that the fluid passes to the process space from the reservoir via the sheet orifices.

The sheet may be sealed to the faceplate, possibly by means of an elastomeric seal such as a perforated sheet or wax, metal or other suitable material, in which case the sealing material must have a melting point greater than the process temperature. Alternatively or additionally, the sheet may be pressed to the showerhead to seal it to at least some of the faceplate orifices.

The sheet may be fitted between the reservoir and the faceplate. Alternatively, the sheet can be fitted within the faceplate, between the faceplace and the process space, or clamped to the faceplate or sandwiched between the faceplate and a backing, baffle or dividing plate so as to seal it to the faceplate.

The centres of at least some of the face plate orifices and the sheet orifices may be substantially aligned and to assist with this an alignment means is preferably provided. The alignment means may include engaging members or shapes on the faceplate and corresponding members or shapes on the sheet so that the correct orientation and location of the sheet with respect to the faceplate can be controlled.

The showerhead may include a further sheet (e.g. a seal) adjacent the first sheet, the orifices of the further sheet being larger in size than the orifices of the first sheet, the first sheet and the further sheet being arranged such that fluid flows through the orifices of both sheets. The further sheet may be formed of an elastomeric material.

In one embodiment, the showerhead includes a dividing plate having a plurality of orifices, the dividing plate defining two reservoirs and the sheet is fitted adjacent the dividing plate. The sheet may be fitted between the dividing plate and the orifices of the faceplate. This embodiment allows the sheet to seal the dividing plate to the faceplate there by separating the two gasses and define the restrictive orifices for one or both gasses. The showerhead may include a further gas inlet for supplying the second of the two reservoirs.

It should be understood that the sheet orifices need not be of uniform size and may differ in size as required to achieve a selected gas flow for example uniform or selectively higher at or on the outer recess of the faceplate and particularly if the sheet is attached to the process side of the faceplate the sheet may be made of or include a material that assists the process carbon or silicon and/or one that scavenges free fluorine from a plasma etch process.

The sheet may be formed of a single material, composite or assembly of e.g. an elastomeric material and metal. Alternatively, and particularly if the sheet is attached to the process side of the faceplate the sheet may be made of, or include a material that assists the process carbon or silicon and/or one that scavenges free fluorine from a plasma etch process. The sheet orifices may be less than 0.5 mm in diameter and most preferably about 0.15 mm in diameter, although smaller sizes are not excluded.

According to a second aspect of the present invention is provided a method of manufacturing a showerhead, the method including steps of:

forming a plurality of orifices in a sheet, and

fitting the sheet in a showerhead having a gas inlet leading to a gas reservoir and a faceplate fitted between the reservoir and a processing space, the sheet being fitted in or on the showerhead such that fluid passes from the reservoir to the processing space via the sheet orifices as well as the faceplate orifices,

wherein the size of the sheet orifices is less than the size of the faceplate orifices.

The orifices may be formed by photoetching, spark erosion, die cutting, moulding, stamping, laser forming, plasma etching or any suitable means.

According to a further aspect of the present invention there is provided a sheet adapted for fitting in a showerhead for substrate processing, the sheet including a plurality of orifices of diameter smaller than the diameter of orifices in a faceplate of a showerhead into which the sheet is to be fitted.

The thickness of the sheet may be less than 1 mm. The sheet may be formed at least partially of an elastomeric material.

Embodiments of the invention provide a thin sheet material such as a foil suitable for photo etching, laser forming or the like in which the desired showerhead hole pattern is formed in terms of orifice size, location and number. These holes may be extremely small, and in general the smaller the holes, the thinner the material in which they can be formed. This sheet can be pressed to a faceplate such that there is no significant leakage between adjacent holes in the foil, e.g. by means of an elastomeric sheet.

In a particular arrangement the sheet may be at least in part an elastomeric material that may also function as a seal between parts of a showerhead and in particular between gasses in a duplex showerhead.

Whilst the invention has been described above, it extends to any inventive combination of the features set out above or in the following description.

### BRIEF DESCRIPTION OF THE DRAWINGS

The invention may be performed in various ways, and by way of example only, an embodiment thereof will now be described, reference being made to the accompanying drawings, in which:—

FIG. 1 shows a general view of showerhead;

FIG. 2 details a showerhead according to an embodiment of the invention that includes a foil;

FIG. 3 is a plan view of the foil;

FIG. 4 details a prior art dual gas showerhead, and

FIG. 5 details a further embodiment providing a dual showerhead.

### DETAILED DESCRIPTION OF THE DRAWINGS

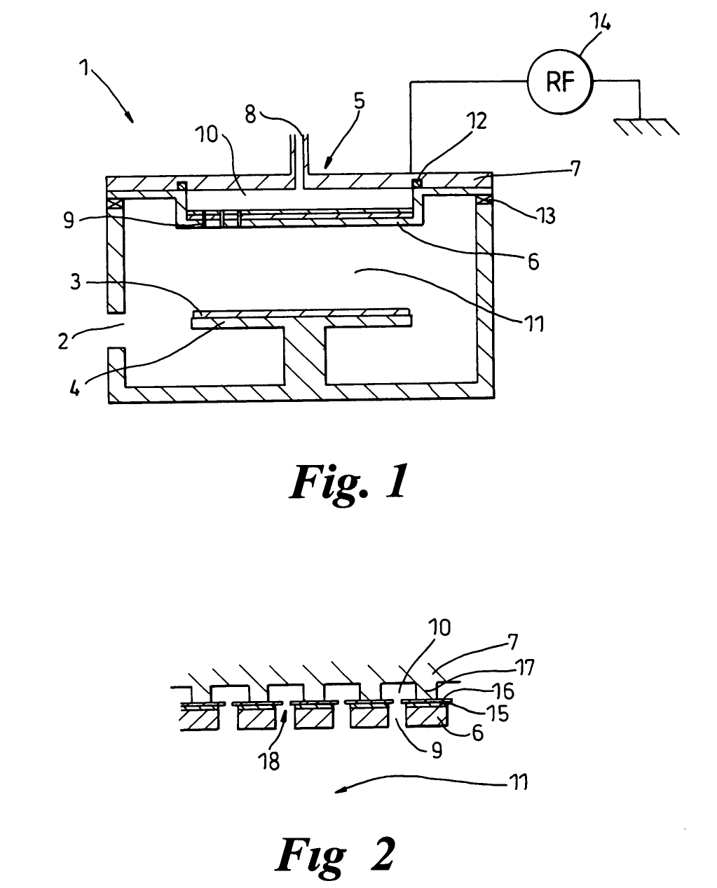

FIG. 1 shows a vacuum processing chamber generally indicated at 1. A pumping orifice 2 connects the chamber to a pump (not shown). Substrates are loaded via a doorway and mechanical handling apparatus which are well known in the art and so are not shown. The substrate 3 to be processed is placed upon a platen 4 that may be temperature controlled, electrically driven and can include clamping means for the wafer, e.g. an electrostatic clamp.

A showerhead assembly shown generally at 5 consists of a faceplate 6 and a backing plate 7 with a gas inlet 8. Holes 9 are formed through the faceplate. A volume 10 between the faceplate and the backing plate acts as a gas reservoir to allow conduction between the gas inlet 8 and the process volume 11. Suitable seals are provided, e.g. at 12 (between the faceplate and the backing plate) and at 13 (between the faceplate and the top of the chamber). Electrical power (shown diagrammatically at 14) may be provided by means well known in the art. It is understood that FIG. 1 merely illustrates some of the general aspects of a showerhead.

FIG. 2 details a showerhead according to an embodiment of the invention. A faceplate 6 has holes 9 that allow fluid communication between the reservoir 10 and the process space 11. A sheet 16 is fitted on the reservoir side of the faceplate 6. The sheet includes a plurality of orifices 18 that are substantially smaller than the holes 9 in the faceplate 6. Thus, the sheet orifices 18 define the control orifices that control fluid flow between the process volume 11 and the reservoir 10.

This sheet is sealed to the faceplate by a seal 15 that may be an elastomeric sheet. When pressure is required for the sealing then parts 17 projecting down from the plate 7 may engage upon the sheet to seal it to the faceplate. The sheet 16 may be a foil or an elastomeric or plastic sheet or in fact any thin material into which sub 1 mm holes may be easily formed.

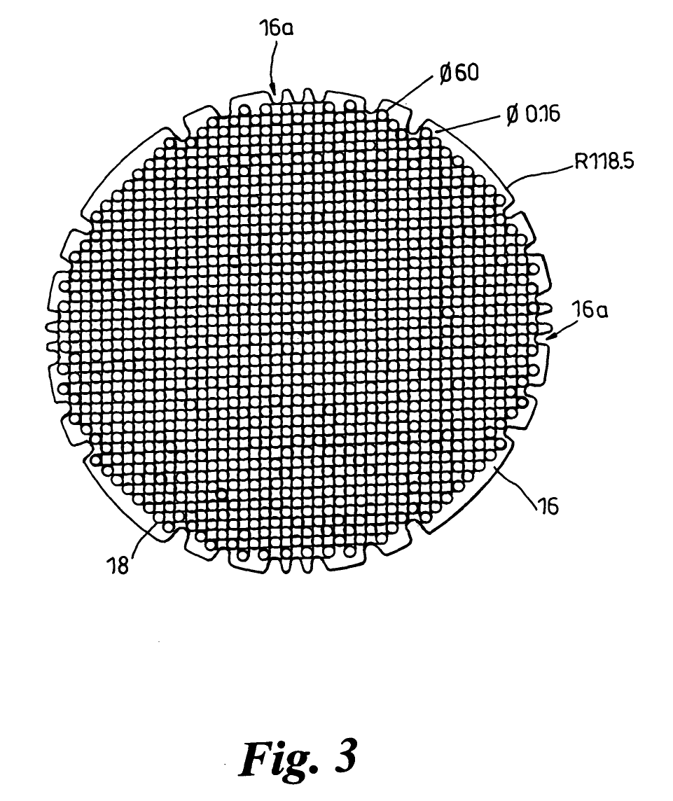

FIG. 3 shows an example of the sheet 16 that has control orifices 18 photoetched through it. The sheet is generally circular with portions 16a cut away around its diameter to facilitate its location and orientation with respect to the faceplate. The sheet 16 controls only one of the two gas flows of a duplex showerhead and so only some of the holes are control orifices and others are not.

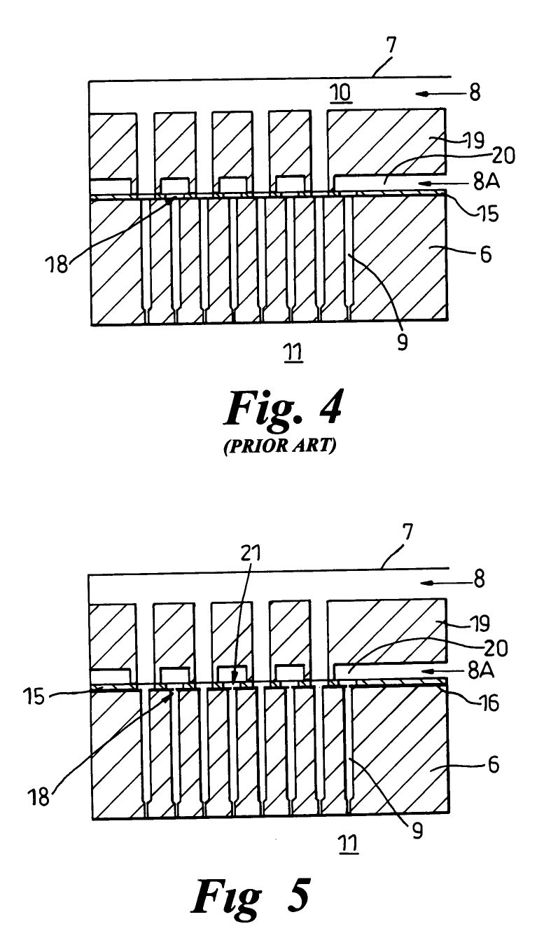

FIG. 4 illustrates a prior art example of a dual gas showerhead. In this case, a seal 15 seals a faceplate 6 to a dividing plate 19 where none of the holes through the seal are flow control orifices. The faceplate 6 is of the type where the diameter of its bores 9 varies. The portion of the bores adjacent the processing volume 11 is narrower than the remaining portion of the bores. The narrower portions are the flow controlling orifices. A first gas inlet 8 allows gas to enter a showerhead reservoir 10 defined between the backing plate 7 and the upper surface of the dividing plate 19. A second gas inlet 8A allows gas to enter the showerhead into a space 20 between the lower surface of the dividing plate 19 and the upper surface of the seal 15. Thus, two different gasses can be passed through the showerhead to the process space 11. The two gases remain separate from one another before they reach the process space 11. The orifices 21 of the seal 15 have larger diameters than any part of the faceplate holes 9.

Turning to the embodiment of FIG. 5, this is similar to the prior art of FIG. 4 but further includes a sheet 16 fitted between the lower surface of the seal 15 and the upper surface of the faceplate 6. The sheet 16 includes a plurality of apertures 18 smaller in diameter than the faceplate orifices 9, or the seal orifices 21. In addition or as an alternative to the embodiment shown in FIG. 5, the sheet 16 may be fitted between the upper surface of the seal 15 and lower surface of the dividing plate 19, The sheet can also be used in connection with showerheads having different types of bores to the ones shown in FIGS. 4 and 5. For example, the sheet could be fitted in a showerhead including the bores shown in FIG. 8 or 9 to 12 of U.S. Pat. No. 6,024,779 or FIG. 2 or 3 of U.S. Pat. No. 4,854,263.

It will be understood that in addition, or as an alternative to the embodiment shown in FIG. 5, a foil 16 can be fitted on top of the dividing plate 19 to control the flow of fluid between the reservoir 10 and the process volume 11.

Various other advantageous arrangements may be employed depending on specific requirements. The seal 15 may be formed by a wax, metal or other material that may be heated to melt at a temperature above that of the process and below that which damages the faceplate. In such a case the mechanical clamping part 17 may not be required. Alternatively, the sheet may be a single assembly with the seal, or may be integral with the seal, i.e. the functionality of seal and control orifice can be combined in a single component. Thus the seal 15 and foil 16 can be one and the same part (e.g. an elastomeric seal) with control orifices 18 formed in it by, e.g., photo etching.

A major advantage provided by embodiments of the invention is that the control orifices that control fluid flow to the process volume are formed in a thin sheet material that may be economically exchanged without replacing the faceplate of the showerhead. It is also considerably easier to form very small holes in thin sheet materials than in gas distribution faceplates. Photo etching can form holes as small as 0.15 mm in sheets less than 1 mm thickness and spark erosion can make holes of 0.1 mm in diameter. Such control orifice holes may therefore be more numerous than if drilled in a faceplate and are also smooth bored and clean as they have not been drilled. Drilling requires cutting and cooling fluids that must in turn be removed from the small holes which are in turn not smooth bored and have associated burrs. This presents major problems where the gasses and processes must be very clean, e.g. for semiconductor wafer processing. The faceplate of the invention primarily acts as a thermal and electrical surface generally opposing the substrate and the holes through its thickness do not control the gas flow. The increased size of the holes through the thickness of the faceplate eases manufacture and cleaning.

An important feature of the showerheads is that the fluid conductance of the holes through the faceplate will always be greater than the fluid conductance of the foil/seal assembly.

Another advantage of this arrangement is where a plasma is present in the process volume. Plasmas may be particularly intense in holes due to the ‘hollow cathode’ effect. By placing the foil behind or within the faceplate, the control orifices may be protected from plasma damage and thus retaining their critical dimensions to control gas flow. The faceplate orifices may be optimised to stop plasma reaching the control office.

In an alternative arrangement the foil 16 is bonded to the process side surface of the showerhead faceplate. This can be useful where the surface exposed to the process volume requires replacement or is in some way consumed by the process and/or is made of expensive material. For example a silicon or carbon or silicon carbide foil may be bonded to the front face of an aluminium showerhead faceplate. The foil may be bonded to the showerhead faceplate by any suitable means, e.g. by means of a low melt temperature metal. This foil may originate as a silicon wafer that has through holes etched in it.

Advantages of embodiments of this invention include the low cost and accuracy of forming the gas flow restricting orifices independently of the other requirements of a showerhead, being mechanical strength, electrical and heat conductivity. The faceplate holes may be considerably bigger than the holes in the sheet as they no longer form the flow control orifice and this greatly eases the manufacture and cleaning of the faceplate.

It is to be understood that the holes 18 that control gas flow need not be of the same size nor need there be a hole 18 for every faceplate hole 9, thus ‘blind holes’ may be created in the process side of the faceplate by an absence of a foil hole 18 aligning with a faceplate hole 9.

We claim:

1. A showerhead for substrate processing including:
a gas inlet leading to a gas reservoir;
a faceplate fitted between the reservoir and a processing space, the faceplate including a plurality of orifices, and
a sheet including a plurality of orifices, the sheet orifices being smaller in size than the minimum diameter of the faceplate orifices,
wherein the sheet is fitted in or on the showerhead such that the fluid passes to the process space from the reservoir via the sheet orifices.

2. A showerhead according to claim 1, wherein the sheet is sealed to the faceplate.

3. A showerhead according to claim 1, wherein the sheet is attached into or on the faceplate.

4. A showerhead according to claim 1, wherein the sheet is fitted between the reservoir and the faceplate.

5. A showerhead according to claim 1, wherein the sheet is fitted between the reservoir and the faceplate and wherein at least some of the faceplate orifices are not aligned with the sheet orifices.

6. A showerhead according claim 1, wherein the sheet is fitted between the faceplace and the process space.

7. A showerhead according to claim 1, wherein the sheet is fitted between the faceplace and the process space and the sheet is formed of a fluorine scavenging material.

8. A showerhead according to claim 1, wherein the sheet is fitted between the faceplace and the process space and the sheet includes silicon or carbon.

9. A showerhead according to claim 1, wherein the centres of faceplate orifices and the sheet orifices are substantially aligned.

10. A showerhead according to claim 1, wherein the showerhead further includes a dividing plate having a plurality of orifices, the dividing plate defining two reservoirs and the sheet is fitted adjacent the dividing plate.

11. A showerhead according to claim 1, wherein the showerhead further includes a dividing plate having a plurality of orifices, the dividing plate defining two reservoirs and the sheet is fitted adjacent the dividing plate and wherein the sheet is fitted between the dividing plate orifices and the orifices of the faceplate.

12. A showerhead according to claim 1, wherein the showerhead further includes a further sheet adjacent the first sheet, the orifices of the further sheet being larger in size than the orifices of the first sheet, the first sheet and the further sheet being arranged such that fluid flows through the orifices of both sheets.

13. A showerhead according to claim 1, wherein the sheet is formed of an elastomeric material or a metal or a plastic.

14. A showerhead according to claim 1, wherein the showerhead further includes a further sheet adjacent the first sheet, the orifices of the further sheet being larger in size than the orifices of the first sheet, the first sheet and the further sheet being arranged such that fluid flows through the orifices of both sheets and wherein the further sheet is formed of an elastomeric material.

15. A showerhead according to claim 1, wherein the sheet orifices are approximately 0.5 mm or less in diameter.

16. A showerhead according to claim 1, wherein the sheet orifices are approximately 0.15 mm in diameter.

17. A method of manufacturing a showerhead for substrate processing, the method including steps of:
forming a plurality of orifices in a sheet, and
fitting the sheet in a showerhead having a gas inlet leading to a gas reservoir and a faceplate fitted between the reservoir and a processing space, the sheet being fitted in or on the showerhead such that fluid passes from the reservoir to the processing space via the sheet orifices,
wherein the size of the sheet orifices is less than the minimum diameter of orifices in the faceplate.

18. A method according to claim 17, wherein the orifices are formed by photoetching, spark erosion, laser forming, moulding, stamping, die cutting or plasma etching.

19. A sheet adapted for fitting in a showerhead for substrate processing, the sheet including a plurality of orifices of diameter smaller than the minimum diameter of orifices in a faceplate of the showerhead into which the sheet is to be fitted.

20. A sheet according to claim 19, wherein the thickness of the sheet is less than 1 mm.

21. A sheet according to claim 19 formed at least in part of an elastomeric material.
